(19) United States
(12) Patent Application Publication
(10) Pub. No.: US 2026/0156928 A1
(43) Pub. Date: Jun. 4, 2026

(54) SEMICONDUCTOR DEVICE

(71) Applicant: Renesas Electronics Corporation, Tokyo (JP)

(72) Inventors: Yuki YAMAMOTO, Tokyo (JP); Hidenori SATO, Tokyo (JP); Fumitoshi TAKAHASHI, Tokyo (JP)

(21) Appl. No.: 19/336,955

(22) Filed: Sep. 23, 2025

(30) Foreign Application Priority Data
Dec. 2, 2024 (JP) 2024-209443

(51) Int. Cl. H10D 84/83; H01L 23/58

(52) U.S. Cl. CPC H10D 84/839; H10W 42/00

(57) ABSTRACT

A semiconductor device includes an n-type semiconductor substrate, a seal ring wiring formed in an annular shape so as to surround a first region and a second region of the semiconductor substrate in plan view, and a p-type impurity region formed in the semiconductor substrate. The impurity region is provided between the first region and the second region so as to extend to a position overlapping, in plan view, with the seal ring wiring. A ground potential is supplied to the impurity region.

### CROSS-REFERENCE TO RELATED APPLICATIONS

The disclosure of Japanese Patent Application No. 2024-209443 filed on Dec. 2, 2024 including the specification, drawings and abstract is incorporated herein by reference in its entirety.

### BACKGROUND

The present invention relates to a semiconductor device.

There are disclosed techniques listed below.

[Patent Document 1] Japanese Unexamined Patent Application Publication No. 2015-88617

A semiconductor device in which two output power Metal Oxide Semiconductor Field Effect Transistors (MOSFETs) and a control circuit for controlling operations of each of the two output power MOSFETs are mounted together has been developed. For example, Patent Document 1 discloses an Intelligent Power Device (IPD) as such a semiconductor device.

The semiconductor device of Patent Document 1 includes a first region in which one of the output power MOSFETs is formed, a second region in which the other output power MOSFET is formed, and a third region in which a MOSFET for a control circuit is formed.

In addition, Patent Document 1 also discloses the following problem. An electric noise having a high potential higher than a drain potential may be applied from the outside of the semiconductor device to a source electrode constituting an output terminal of the power MOSFET of the first region. In such a case, a parasitic current flows from a p-type body region of the first region to an n-type semiconductor substrate. At this point, a leakage current as part of the parasitic current flows from the p-type body region of the first region to a p-type body region of the second region. Furthermore, a leakage current also flows from the p-type body region of the first region to a p-type well region of the third region.

Such leakage currents cause malfunction in the power MOSFET of the second region and in the MOSFET of the third region.

### SUMMARY

In Patent Document 1, in order to absorb the leakage currents as described above, a p-type impurity region is formed in a semiconductor substrate. The p-type impurity region is provided between the first region and the second region, between the first region and the third region, and between the second region and the third region. By connecting a battery potential (drain potential) to the p-type impurity region, the leakage currents are absorbed into the p-type impurity region. Therefore, malfunction in the power MOSFET of the second region and in the MOSFET of the third region can be suppressed.

In recent IPDs, miniaturization of semiconductor devices has been promoted, and requirements for suppression of leakage currents have become stricter. In order to further suppress leakage currents and improve reliability of semiconductor devices, it may be considered, for example, to provide a p-type impurity region so as to surround each of the first region, the second region, and the third region in plan view. However, in that case, a plane area for providing the p-type impurity region increases, and a planar size of the semiconductor device increases, so that promotion of miniaturization of the semiconductor device becomes difficult. Accordingly, there is a demand for a technique capable of suppressing an increase in the planar size of the semiconductor device, suppressing leakage currents, and improving reliability of the semiconductor device.

Other problems and novel features will become apparent from the description of the present specification and the accompanying drawings.

Among the embodiments disclosed in the present application, a summary of a representative embodiments will be briefly described as follows.

A semiconductor device according to one embodiment includes a semiconductor substrate of a first conductivity type, a seal ring wiring formed in an annular shape so as to surround a first region and a second region of the semiconductor substrate in plan view, and an impurity region formed in the semiconductor substrate and having a second conductivity type opposite to the first conductivity type. The impurity region is provided between the first region and the second region so as to extend to a position overlapping, in plan view, with the seal ring wiring. A ground potential is supplied to the impurity region.

A semiconductor device according to one embodiment includes a semiconductor substrate of a first conductivity type, a seal ring wiring formed in an annular shape so as to surround a first region and a second region of the semiconductor substrate in plan view, and an impurity region formed in the semiconductor substrate and having a second conductivity type opposite to the first conductivity type. The impurity region is provided between the first region and the second region, and between the seal ring wiring and a portion of the second region. A ground potential is supplied to the impurity region.

According to one embodiment, it is possible to suppress an increase in the planar size of the semiconductor device and improve the reliability of the semiconductor device.

### BRIEF DESCRIPTION OF THE DRAWINGS

FIG. 1 is a plan view illustrating a semiconductor device according to a first embodiment.

FIG. 2 is a plan view illustrating the semiconductor device according to the first embodiment.

FIG. 3 is a cross-sectional view illustrating the semiconductor device according to the first embodiment.

FIG. 4 is a cross-sectional view illustrating the semiconductor device according to the first embodiment.

FIG. 5 is a cross-sectional view illustrating the semiconductor device according to the first embodiment.

FIG. 6 is a cross-sectional view illustrating a parasitic current and a leakage current occurring in the first embodiment.

FIG. 7 is a plan view illustrating a semiconductor device according to a first modification.

FIG. 8 is a plan view illustrating a semiconductor device according to a second modification.

FIG. 9 is a plan view illustrating a semiconductor device according to a third modification.

FIG. 10 is a plan view illustrating a semiconductor device according to a fourth modification.

FIG. 11 is a plan view illustrating a semiconductor device according to a fifth modification.

FIG. 12 is a cross-sectional view illustrating the semiconductor device according to the fifth modification.

FIG. 13 is a plan view illustrating a semiconductor device according to a second embodiment.

FIG. 14 is a plan view illustrating a semiconductor device according to an examination example.

### DETAILED DESCRIPTION

Hereinafter, embodiments will be described in detail with reference to the drawings. In all the drawings for illustrating the embodiments, members having the same function are denoted by the same reference numerals, and repeated description thereof will be omitted. In addition, in the following embodiments, descriptions of the same or similar parts will not be repeated in principle unless particularly necessary.

An X direction, a Y direction, and a Z direction described in the present application intersect each other and are orthogonal to each other. In the present application, the Z direction will be described as a vertical direction, a depth direction, or a thickness direction of a structure. In addition, expressions such as “plan view” or “planer view” used in the present application mean that a plane constituted by the X direction and the Y direction is defined as a “plane”, and that this “plane” is viewed from the Z direction.

### First Embodiment

### <Structure of Semiconductor Device>

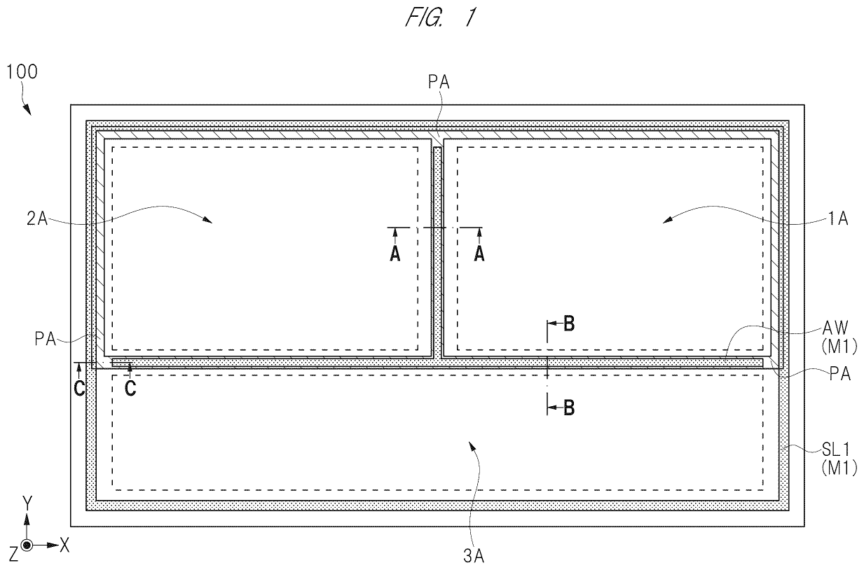

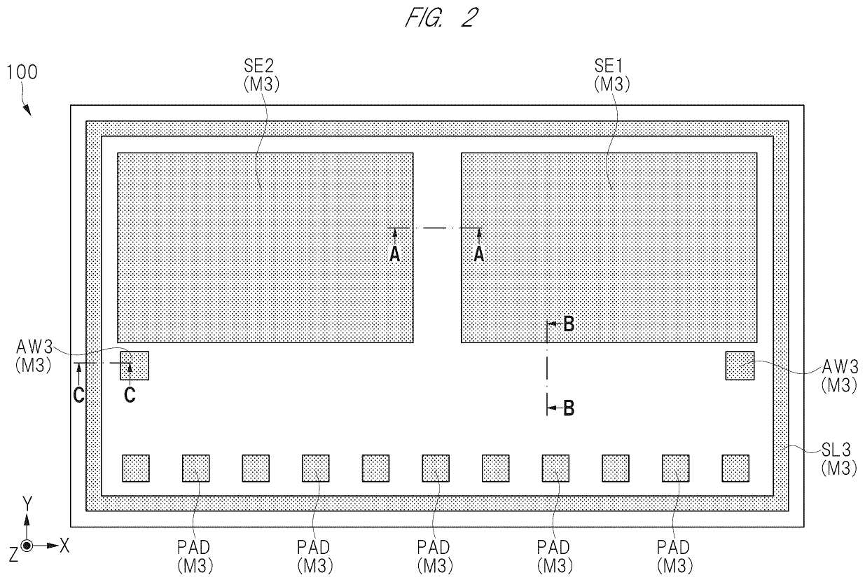

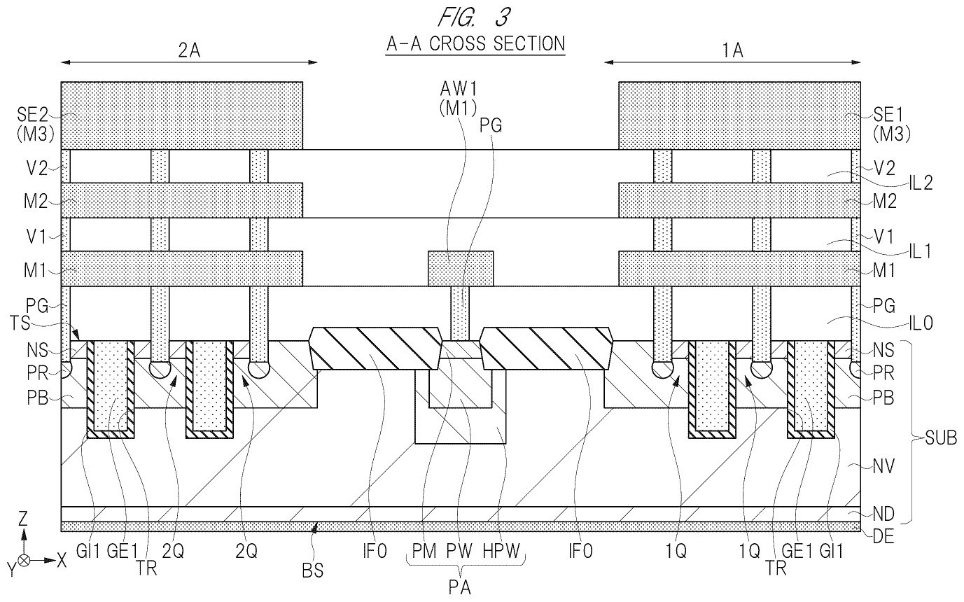

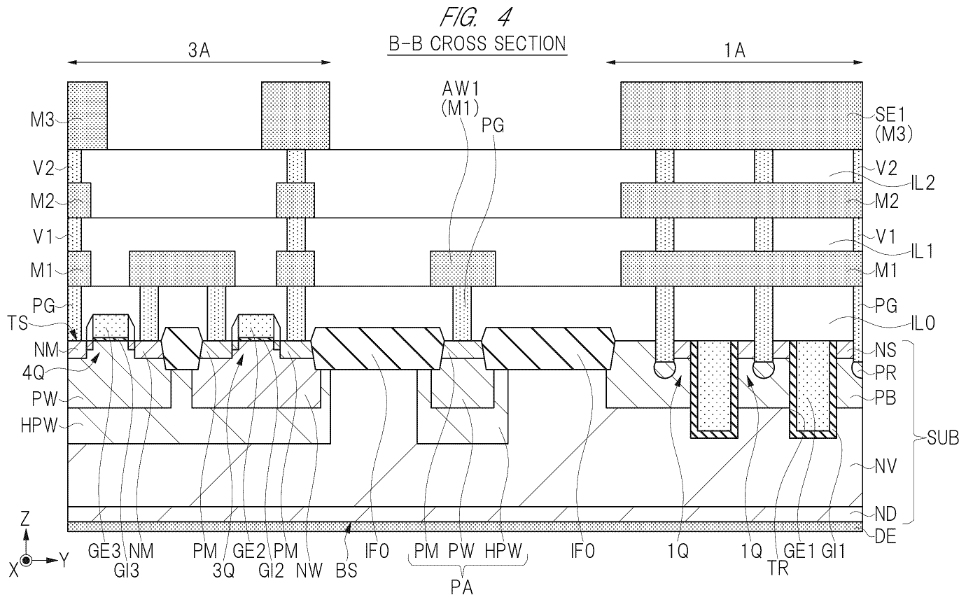

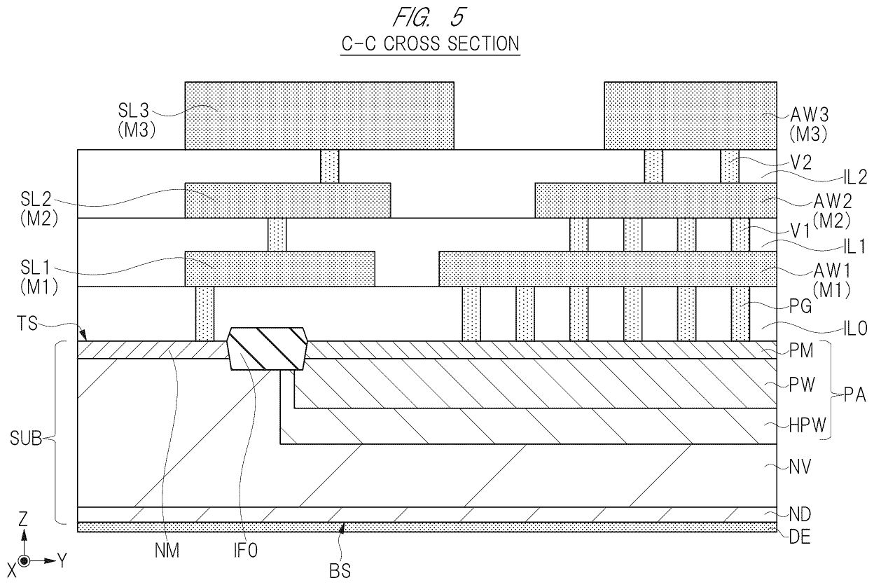

With reference to FIGS. 1 to 5, a structure of a semiconductor device (semiconductor chip) 100 according to a first embodiment will be described. FIG. 1 is a plan view illustrating the semiconductor device 100. FIG. 2 is a plan view illustrating a wiring layer above the layer of FIG. 1. FIG. 3 is a cross-sectional view taken along line A-A illustrated in FIGS. 1 and 2. FIG. 4 is a cross-sectional view taken along line B-B illustrated in FIGS. 1 and 2. FIG. 5 is a cross-sectional view taken along line C-C illustrated in FIGS. 1 and 2.

As illustrated in FIG. 1, the semiconductor device 100 includes a region 1A, a region 2A located adjacent to the region 1A, and a region 3A located adjacent to the region 1A and adjacent to the region 2A. In addition, as illustrated in FIGS. 3, 4, and 5, the semiconductor device 100 includes an n-type semiconductor substrate SUB having an upper surface TS and a lower surface BS. As illustrated in FIGS. 3 and 4, a plurality of n-type power MOSFETs 1Q is formed in a region (a first region) of the semiconductor substrate SUB corresponding to the region 1A. As illustrated in FIG. 3, a plurality of n-type power MOSFETs 2Q is formed in a region (a second region) of the semiconductor substrate SUB corresponding to the region 2A. Further, the semiconductor device 100 includes a control circuit for controlling operation of each of the plurality of power MOSFETs 1Q and the plurality of power MOSFETs 2Q. As illustrated in FIG. 4, a plurality of p-type MOSFETs 3Q and a plurality of n-type MOSFETs 4Q, which constitute part of the control circuit, are formed in a region (a third region) of the semiconductor substrate SUB corresponding to the region 3A.

As illustrated in FIGS. 3, 4, and 5, the semiconductor device 100 includes a plurality of wirings M1 formed above the semiconductor substrate SUB, a plurality of wirings M2 formed above the plurality of wirings M1, and a plurality of wirings M3 formed above the plurality of wirings M2.

The plurality of wirings M1 includes an absorption wiring AW1 and a seal ring wiring SL1. FIG. 1 illustrates the absorption wiring AW1 and the seal ring wiring SL1. The seal ring wiring SL1 is formed in an annular shape so as to surround the region 1A (that is, the first region of the semiconductor substrate SUB), the region 2A (that is, the second region of the semiconductor substrate SUB), and the region 3A (that is, the third region of the semiconductor substrate SUB) in plan view. Although not illustrated here, a seal ring wiring SL2 and a seal ring wiring SL3 electrically connected to the seal ring wiring SL1 are also formed in an annular shape so as to surround the region 1A, the region 2A, and the region 3A in plan view.

In the semiconductor substrate SUB, an absorption region PA as a p-type impurity region is formed. The absorption region PA is provided between the region 1A and the region 2A, between the region 1A and the region 3A, and between the region 2A and the region 3A. In addition, the absorption region PA extends to a position overlapping with the seal ring wiring SL1 in plan view. Furthermore, in the first embodiment, the absorption region PA also overlaps, in plan view, with a portion of the seal ring wiring SL1 that surrounds the region 1A and the region 2A.

Although not illustrated here, the absorption region PA extends to a position overlapping with the seal ring wiring SL2 and the seal ring wiring SL3 located above the seal ring wiring SL1. In addition, the absorption region PA also overlaps, in plan view, with portions of the seal ring wiring SL2 and the seal ring wiring SL3 that surround the region 1A and the region 2A.

The absorption wiring AW1 is formed on the absorption region PA and is electrically connected to the absorption region PA. The absorption wiring AW1 is provided between the region 1A and the region 2A, between the region 1A and the region 3A, and between the region 2A and the region 3A so as to cover a portion of the absorption region PA in plan view. The absorption wiring AW1 is separated from the seal ring wiring SL1.

A ground potential is supplied to the absorption region PA via the absorption wiring AW1. As described later, the seal ring wiring SL1 is electrically connected to a drain electrode DE via the semiconductor substrate SUB. Therefore, a drain potential is supplied to the seal ring wiring SL1. The absorption region PA and the absorption wiring AW1 are electrically insulated from the seal ring wiring SL1.

FIG. 2 illustrates the seal ring wiring SL3, a source electrode SE1, a source electrode SE2, a plurality of pads PAD, and a plurality of absorption wirings AW3 among the plurality of wirings M3. The source electrode SE1 is electrically connected to a source region NS and a body region PB of the power MOSFET 1Q. The source electrode SE2 is electrically connected to a source region NS and a body region PB of the power MOSFET 2Q. The plurality of pads PAD is electrically connected to the MOSFETs 3Q and the MOSFETs 4Q.

By connecting an external connection member to upper surfaces of the seal ring wiring SL3, the source electrode SE1, the source electrode SE2, the plurality of pads PAD, and the plurality of absorption wirings AW3, the semiconductor device 100 is electrically connected to another semiconductor chip, a lead frame, or a wiring substrate. The external connection member is, for example, a wire made of aluminum, gold, or copper, or a clip made of a copper plate.

The absorption wiring AW3 is electrically connected to the absorption region PA via an absorption wiring AW2 and the absorption wiring AW1. By connecting a terminal for ground potential provided outside the semiconductor device 100 and the absorption wiring AW3 with the external connection member, the ground potential is supplied to the absorption region PA.

Hereinafter, the cross-sectional structure of the semiconductor device 100 will be described with reference to FIGS. 3 to 5.

As illustrated in FIGS. 3 to 5, the semiconductor device 100 includes the n-type semiconductor substrate SUB having the upper surface TS and the lower surface BS. The semiconductor substrate SUB is made of n-type silicon. The semiconductor substrate SUB has an n-type drift region NV and an n-type drain region ND. An impurity concentration of the drain region ND is higher than an impurity concentration of the drift region NV.

The semiconductor substrate SUB may be a laminate of an n-type silicon substrate and an n-type silicon layer grown on the above silicon substrate while introducing n-type impurities by an epitaxial growth method. In this case, the above silicon layer constitutes the drift region NV, and the above silicon substrate constitutes the drain region ND. A resistivity of the silicon substrate is 1.0 Ω·cm or more and 2.5 Ω·cm or less, and a resistivity of the silicon layer is 0.158 Ω·cm or more and 0.160 Ω·cm or less.

A drain electrode DE is formed on the lower surface BS of the semiconductor substrate SUB. The drain electrode DE is made of, for example, a single-layer metal film such as an aluminum film, a titanium film, a nickel film, a gold film, or a silver film, or a laminated film obtained by appropriately laminating these metal films. The drain electrode DE is formed over the entire lower surface BS of the semiconductor substrate SUB. A drain potential is supplied from the drain electrode DE to the semiconductor substrate SUB (the drain region ND and the drift region NV).

Hereinafter, the cross-sectional structure of the region 1A and the cross-sectional structure of the region 2A will be described with reference to FIG. 3. Since the cross-sectional structure of the power MOSFET 2Q in the region 2A is substantially the same as the cross-sectional structure of the power MOSFET 1Q in the region 1A, the cross-sectional structure of the power MOSFET 1Q will be described representatively here.

As illustrated in FIG. 3, trenches TR are formed in the semiconductor substrate SUB so as to reach a predetermined depth from the upper surface TS of the semiconductor substrate SUB. In the trench TR, a gate electrode GE1 is formed via a gate insulating film GI1. The gate insulating film GI1 is, for example, a silicon oxide film. The gate electrode GE1 is, for example, a polycrystalline silicon film into which n-type impurities are introduced.

In the semiconductor substrate SUB, a p-type body region PB of is formed so that a depth from the upper surface TS of the semiconductor substrate SUB is shallower than the depth of the trench TR. In the body region PB, an n-type source region NS is formed. An impurity concentration of the source region NS is higher than the impurity concentration of the drift region NV. In the body region PB, a portion adjacent to the gate electrode GE1 via the gate insulating film GI1 and located between the source region NS and the drift region NV constitutes a channel region of the power MOSFET 1Q. That is, the power MOSFET 1Q in the present embodiment is a so-called vertical field-effect transistor (power semiconductor) in which a current flows in a thickness direction of the semiconductor substrate SUB.

On the upper surface TS of the semiconductor substrate SUB, an interlayer insulating film IL0 is formed so as to cover the trenches TR. The interlayer insulating film IL0 is made of, for example, a silicon oxide film. In the interlayer insulating film IL0, holes are formed so as to penetrate the source region NS and reach the body region PB. At a bottom of the hole, a diffusion region PR is formed in the body region PB. The diffusion region PR has a higher impurity concentration than the body region PB. The diffusion region PR is provided mainly for reducing a contact resistance with a plug PG and for preventing latch-up.

In the hole, the plug PG is formed. The plug PG is electrically connected to the source region NS, the body region PB, and the diffusion region PR. The plug PG includes, for example, a first barrier metal film and a first conductive film formed on the first barrier metal film. The first barrier metal film is, for example, a laminated film of a titanium film and a titanium nitride film. The first conductive film is, for example, a tungsten film.

On the interlayer insulating film IL0, a wiring M1 is formed. The wiring M1 is electrically connected to the plug PG. The wiring M1 includes, for example, a second barrier metal film, a second conductive film formed on the second barrier metal film, and a third barrier metal film formed on the second conductive film. The second barrier metal film and the third barrier metal film are each, for example, a laminated film of a titanium film and a titanium nitride film. The second conductive film is, for example, an aluminum alloy film to which copper or silicon is added.

On the interlayer insulating film IL0, an interlayer insulating film IL1 is formed so as to cover the wiring M1. The interlayer insulating film IL1 is made of, for example, a silicon oxide film. In the interlayer insulating film IL1, holes are formed so as to reach the wiring M1. In the hole, a via V1 is formed. The via V1 is electrically connected to the wiring M1. On the interlayer insulating film IL1, a wiring M2 is formed. The wiring M2 is electrically connected to the via V1.

On the interlayer insulating film IL1, an interlayer insulating film IL2 is formed so as to cover the wiring M2. The interlayer insulating film IL2 is made of, for example, a silicon oxide film. In the interlayer insulating film IL2, holes are formed so as to reach the wiring M2. In the above hole, a via V2 is formed. The via V2 is electrically connected to the wiring M2. On the interlayer insulating film IL2, a wiring M3 is formed. The wiring M3 is electrically connected to the via V2.

Structures of the via V2 and the via V1 are similar to a structure of the plug PG and include the first barrier metal film and the first conductive film. Structures of the wiring M3 and the wiring M2 are similar to a structure of the wiring M1 and include the second barrier metal film, the second conductive film, and the third barrier metal film. A thickness of the wiring M3 is greater than a thickness of each of the wiring M2 and the wiring M1.

A source potential is supplied from the source electrode SE1 (the wiring M3) to the source region NS, the body region PB, and the diffusion region PR of the power MOSFET 1Q. A source potential is supplied from the source electrode SE2 (the wiring M3) to the source region NS, the body region PB, and the diffusion region PR of the power MOSFET 2Q.

As illustrated in FIGS. 3 and 4, between the region 1A and the region 2A, between the region 1A and the region 3A, and between the region 2A and the region 3A, a field insulating film IF0 and the absorption region PA are formed in the semiconductor substrate SUB. The field insulating film IF0 is, for example, a silicon oxide film. The absorption region PA is provided in a portion of the semiconductor substrate SUB where the field insulating film IF0 is not formed and is electrically connected to the absorption wiring AW1 via the plugs PG.

In the first embodiment, the absorption region PA includes a p-type well region HPW, a p-type well region PW, and a p-type diffusion region PM as a p-type impurity region constituting the absorption region PA. The well region HPW is formed in the semiconductor substrate SUB so as to reach a predetermined depth from the upper surface TS of the semiconductor substrate SUB. The well region PW is formed in the well region HPW. The diffusion region PM is formed in the well region PW. An impurity concentration of the well region PW is higher than an impurity concentration of the well region HPW. An impurity concentration of the diffusion region PM is higher than the impurity concentration of the well region PW.

The well region HPW, the well region PW, and the diffusion region PM constituting the absorption region PA are formed by the same manufacturing process as a well region HPW, a well region PW, and a diffusion region PM formed in the region 3A described later. It should be noted that the p-type impurity region constituting the absorption region PA are merely an example, and the absorption region PA may be constituted of other p-type impurity region, or may be constituted of a single p-type impurity region.

Hereinafter, the cross-sectional structure of the region 3A will be described with reference to FIG. 4. Although, the semiconductor device 100 includes a control circuit for controlling operation of each of the plurality of power MOSFETs 1Q and the plurality of power MOSFETs 2Q, the semiconductor device 100 may also include other circuits such as a charge pump circuit, a temperature detection circuit, or a current detection circuit. The plurality of p-type MOSFETs 3Q and the plurality of n-type MOSFETs 4Q formed in the region 3A are used not only as a part of the control circuit but also as a part of the other circuits.

As illustrated in FIG. 4, a p-type well region HPW is formed in the semiconductor substrate SUB. In the well region HPW, an n-type well region NW and a p-type well region PW are formed.

On the well region NW, a gate electrode GE2 is formed via a gate insulating film GI2. The gate insulating film GI2 is, for example, a silicon oxide film. The gate electrode GE2 is, for example, a polycrystalline silicon film into which p-type impurities are introduced. In the well region NW, a pair of p-type diffusion regions PM are formed. The pair of diffusion regions PM constitute a source region or a drain region of the MOSFET 3Q. In the well region NW, a portion located below the gate electrode GE2 and between the pair of diffusion regions PM constitutes a channel region of the MOSFET 3Q. That is, the MOSFET 3Q in the present embodiment is a so-called lateral field-effect transistor in which a current flows along the upper surface TS of the semiconductor substrate SUB. An impurity concentration of the well region NW is higher than the impurity concentration of the drift region NV.

On the well region PW, a gate electrode GE3 is formed via a gate insulating film GI3. The gate insulating film GI3 is, for example, a silicon oxide film. The gate electrode GE3 is, for example, a polycrystalline silicon film into which n-type impurities are introduced. In the well region PW, a pair of n-type diffusion regions NM are formed. The pair of diffusion regions NM constitute a source region or a drain region of the MOSFET 4Q. In the well region PW, a portion located below the gate electrode GE3 and between the pair of diffusion regions NM constitutes a channel region of the MOSFET 4Q. That is, the MOSFET 4Q in the present embodiment is a so-called lateral field-effect transistor in which a current flows along the upper surface TS of the semiconductor substrate SUB. An impurity concentration of the diffusion regions NM is higher than the impurity concentration of the drift region NV.

The gate electrode GE2, the diffusion regions PM, the gate electrode GE3, and the diffusion regions NM are electrically connected to the wiring M1 via the plugs PG. By appropriately wiring the plurality of MOSFETs 3Q and the plurality of MOSFETs 4Q using the plugs PG, the wiring M1, the via V1, the wiring M2, the via V2, and the wiring M3, the above-described control circuit and other circuits are constituted.

In addition, connection between the control circuit and each of the gate electrodes GE1 of the plurality of power MOSFETs 1Q and the plurality of power MOSFETs 2Q can be made, for example, by routing the wiring M1 or the wiring M2 from the region 3A to the region 1A and the region 2A.

Hereinafter, a cross-sectional structure around the seal ring wirings SL1, SL2, and SL3 will be described with reference to FIG. 5.

As illustrated in FIG. 5, an n-type diffusion region NM is formed in the semiconductor substrate SUB. The seal ring wiring SL1 is electrically connected to the diffusion region NM via the plug PG. The seal ring wiring SL2 is electrically connected to the seal ring wiring SL1 via the via V1. The seal ring wiring SL3 is electrically connected to the seal ring wiring SL2 via the via V2. The semiconductor substrate SUB (the diffusion region NM, the drift region NV, and the drain region ND) is electrically connected to the drain electrode DE. Accordingly, the drain potential is supplied to the seal ring wirings SL1, SL2, and SL3 from the drain electrode DE via the semiconductor substrate SUB.

The absorption wiring AW1 is electrically connected to the absorption region PA via the plugs PG. The absorption wiring AW2 is electrically connected to the absorption wiring AW1 via the vias V1. The absorption wiring AW3 is electrically connected to the absorption wiring AW2 via the vias V2. The absorption wirings AW1, AW2, and AW3 are separated from the seal ring wirings SL1, SL2, and SL3 and are electrically insulated from the seal ring wirings SL1, SL2, and SL3.

It should be noted that, here, the absorption region PA overlaps, in plan view, with each of the seal ring wirings SL1, SL2, and SL3. However, the absorption region PA only needs to overlap, in plan view, with at least one of the seal ring wirings SL1, SL2, and SL3. In the following description, a case where the absorption region PA overlaps, in plan view, with the seal ring wiring SL1 will be representatively illustrated.

### <Effect of Absorption Region PA>

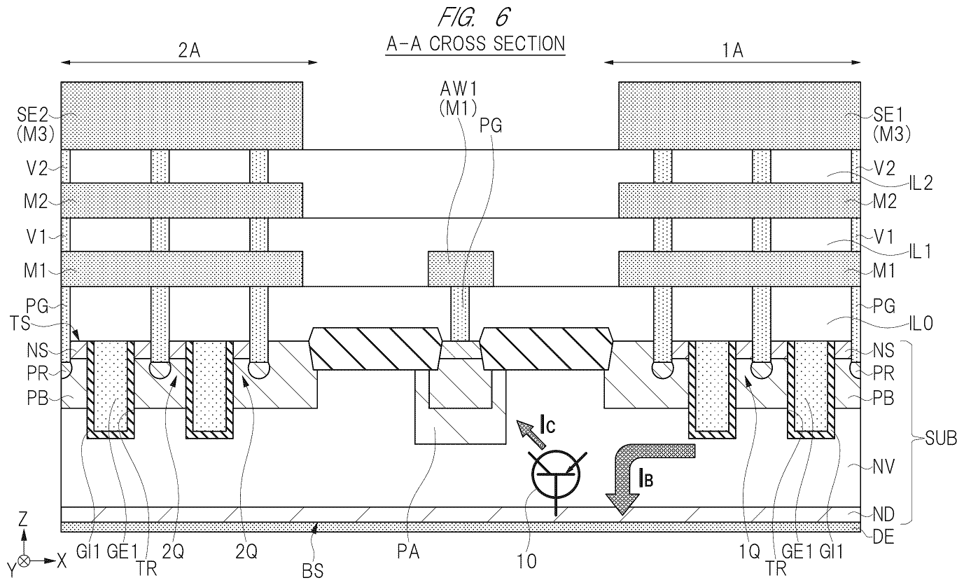

Hereinafter, an effect obtained by providing the absorption region PA will be described with reference to FIG. 6.

In some cases, a high potential higher than the drain potential is applied, as electrical noise, from outside the semiconductor device 100 to the source electrode SE1 that constitutes an output terminal of the power MOSFET 1Q. In such a case, the body region PB of the power MOSFET 1Q is forward biased. Then, as illustrated in FIG. 6, a parasitic current I_{B} flows from the body region PB of the power MOSFET 1Q to the semiconductor substrate SUB.

At this point, a parasitic PNP transistor 10 is formed with the body region PB of the power MOSFET 1Q serving as an emitter, the semiconductor substrate SUB serving as a base, and the body region PB of the power MOSFET 2Q serving as a collector. Accordingly, simultaneously with the parasitic current I_{B} flowing, a leakage current I_{C} as a part of the parasitic current I_{B} flows from the body region PB of the power MOSFET 1Q to the body region PB of the power MOSFET 2Q.

In addition, in the semiconductor substrate SUB in the region 3A, a p-type well region HPW has been formed. Accordingly, another parasitic PNP transistor 10 is also formed with the body region PB of the power MOSFET 1Q serving as an emitter, the semiconductor substrate SUB serving as a base, and the well region HPW of the region 3A serving as a collector. Therefore, a leakage current I_{C} also flows from the body region PB of the power MOSFET 1Q to the well region HPW of the region 3A.

In some cases, a high potential is also applied, as electrical noise, to the source electrode SE2 that constitutes an output terminal of the power MOSFET 2Q. In such a case, a leakage current I_{C} flows from the body region PB of the power MOSFET 2Q to the body region PB of the power MOSFET 1Q, and a leakage current I_{C} flows from the body region PB of the power MOSFET 2Q to the well region HPW of the region 3A.

Such a leakage current I_{C} becomes a factor causing malfunction in the power MOSFETs 1Q, the power MOSFETs 2Q, the MOSFETs 3Q, and the MOSFETs 4Q.

The absorption region PA is provided to absorb such a leakage current I_{C}. The absorption region PA is provided between the region 1A and the region 2A, between the region 1A and the region 3A, and between the region 2A and the region 3A. In addition, a ground potential is connected to the absorption region PA. Then, before the leakage current I_{C} reaches the body region PB or the well region HPW of the region 3A, the leakage current I_{C} is absorbed by the absorption region PA. Therefore, malfunction in the power MOSFETs 1Q, the power MOSFETs 2Q, the MOSFETs 3Q, and the MOSFETs 4Q can be suppressed.

### <Main Features of First Embodiment>

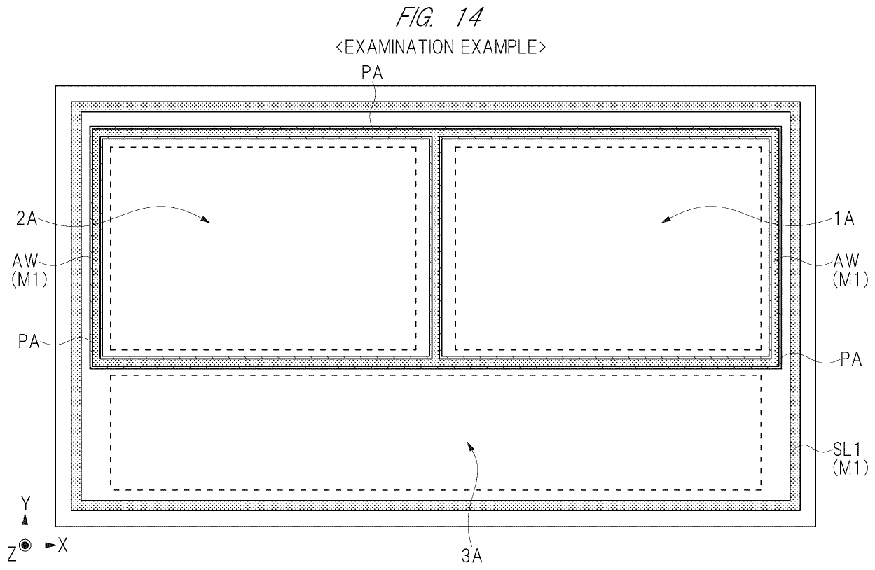

Main features of the first embodiment will be described below. Prior to that, an examination example will be described. FIG. 14 illustrates a semiconductor device of an examination example examined by the present inventors, and illustrates a planar layout of the absorption region PA in the examination example.

As can be understood by comparing FIG. 1 and FIG. 14, in both the first embodiment and the examination example, the absorption region PA surrounds the region 1A and the region 2A in plan view. However, in the examination example, the absorption wiring AW1 also surrounds the region 1A and the region 2A in plan view, and the absorption region PA does not overlap, in plan view, with the seal ring wiring SL1. Although not illustrated here, the absorption region PA does not overlap, in plan view, with the seal ring wirings SL2 and SL3 either.

The absorption region PA and the absorption wirings AW1, AW2, and AW3 need to be electrically insulated from the seal ring wirings SL1, SL2, and SL3. Therefore, in the examination example, the seal ring wirings SL1, SL2, and SL3 are extended outward toward a peripheral edge of the semiconductor device. As a result, in the examination example, a planar size of the semiconductor device increases.

Whereas, in the first embodiment, as illustrated in FIG. 5, the plug PG for connecting the semiconductor substrate SUB and the seal ring wiring SL1 is arranged at a position closer to an outer ring of the seal ring wiring SL1 than to an inner ring of the seal ring wiring SL1. Therefore, as illustrated in FIGS. 1 and 5, it is easier to extend the absorption region PA to a position overlapping, in plan view, with the seal ring wirings SL1, SL2, and SL3.

In addition, although the absorption wiring AW1 is provided between the region 1A and the region 2A, between the region 1A and the region 3A, and between the region 2A and the region 3A, the absorption wiring AW1 is separated from the seal ring wiring SL1, and is not provided between the seal ring wiring SL1 and the region 1A, the region 2A, and the region 3A.

Accordingly, by the absorption region PA of the first embodiment, an increase in a planar size of the semiconductor device 100 is suppressed, the leakage current I_{C} is suppressed, and reliability of the semiconductor device 100 can be improved.

In addition, a potential supplied to the absorption region PA is the ground potential. Compared with a case where the drain potential is supplied to the absorption region PA, a potential difference between a high potential supplied as noise to the source electrode SE1 and the potential supplied to the absorption region PA becomes larger. Therefore, the leakage current I_{C} is more easily attracted to the absorption region PA, and an ability of the absorption region PA to absorb the leakage current I_{C} can be improved. When the ground potential is supplied to the absorption region PA, compared with a case where the drain potential is supplied to the absorption region PA, the ability to absorb the leakage current I_{C} is improved by about 20%.

In addition, a depth of the absorption region PA is greater than a depth of the body region PB of the power MOSFET 1Q and a depth of the body region PB of the power MOSFET 2Q. By providing the relatively deep absorption region PA at a location that becomes a path of the leakage current I_{C}, the leakage current I_{C} is more easily absorbed in the absorption region PA.

### First Modification

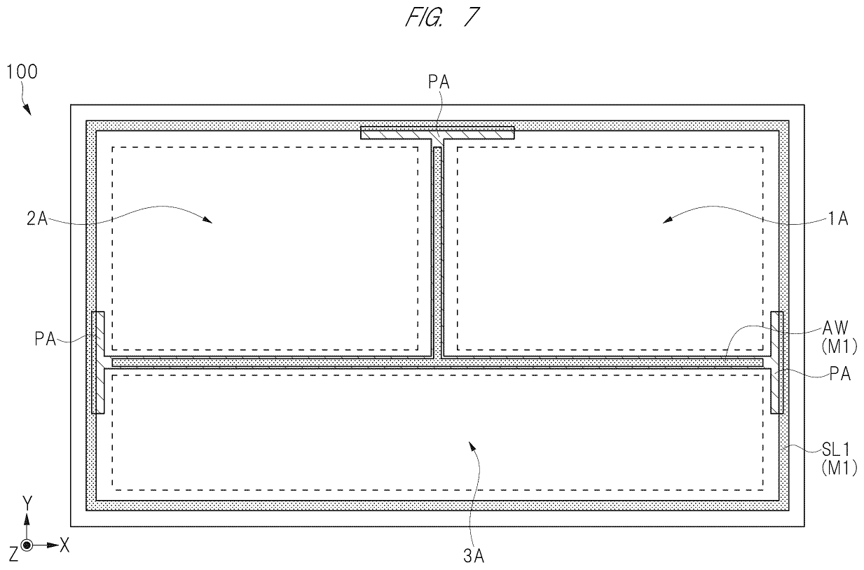

Hereinafter, a semiconductor device 100 according to a first modification of the first embodiment will be described with reference to FIG. 7. In the following description, differences from the first embodiment will mainly be described, and overlapping points with the first embodiment will be omitted.

In the first embodiment, the absorption region PA entirely surrounded each of the regions 1A and 2A in plan view.

As illustrated in FIG. 7, in the first modification, the absorption region PA partially surrounds an outer periphery of each of the region 1A, the region 2A, and the region 3A in plan view. That is, the absorption region PA overlaps, in plan view, with a portion of the seal ring wiring SL1 adjacent to each of the region 1A, the region 2A, and the region 3A.

In other words, in the portion of the absorption region PA provided between the region 1A and the region 2A, the absorption region PA extends to a position overlapping, in plan view, with the seal ring wiring SL1 and partially surrounds the outer periphery of each of the region 1A and the region 2A in plan view. Also, in the portion of the absorption region PA provided between the region 1A and the region 3A, the absorption region PA extends to a position overlapping, in plan view, with the seal ring wiring SL1 and partially surrounds the outer periphery of each of the region 1A and the region 3A in plan view. Also, in the portion of the absorption region PA provided between the region 2A and the region 3A, the absorption region PA extends to a position overlapping, in plan view, with the seal ring wiring SL1 and partially surrounds the outer periphery of each of the region 2A and the region 3A in plan view.

By increasing an area of the absorption region PA, the ability to absorb the leakage current I_{C} can be improved. On the other hand, when the area of the absorption region PA is increased, junction leakage between the absorption region PA and the semiconductor substrate SUB increases. If the junction leakage increases, overall power consumption in the semiconductor device 100 increases.

In the first embodiment, since the absorption region PA entirely surrounds each of the region 1A and the region 2A in plan view, a current path of the leakage current I_{C} from the region 1A to the region 2A or to the region 3A and a current path of the leakage current I_{C} from the region 2A to the region 1A or to the region 3A are blocked. On the other hand, in the first embodiment, it becomes easier to increase the area of the absorption region PA.

Therefore, in the first modification, the current path of the leakage current I_{C} is partially blocked. By detouring the current path of the leakage current I_{C}, the ability to absorb the leakage current I_{C} can be maintained to some extent. The junction leakage can be reduced by the amount corresponding to the reduction in the area of the absorption region PA. Accordingly, in the first modification, compared with the first embodiment, overall power consumption in the semiconductor device 100 can be reduced.

### Second Modification

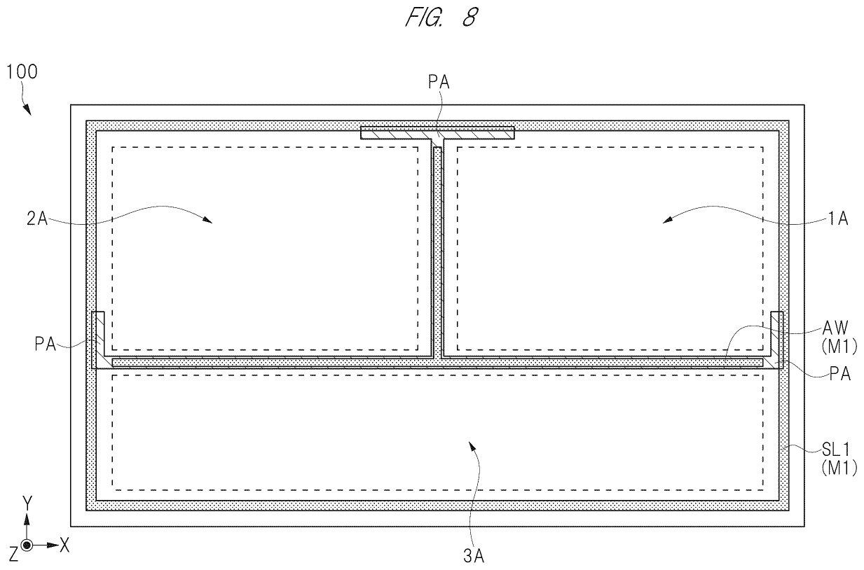

Hereinafter, a semiconductor device 100 according to a second modification of the first embodiment will be described with reference to FIG. 8. In the following description, differences from the first modification will mainly be described, and overlapping points with the first modification will be omitted.

As illustrated in FIG. 8, in the second modification, the absorption region PA partially surrounds an outer periphery of each of the region 1A and the region 2A in plan view. That is, the absorption region PA overlaps, in plan view, with a portion of the seal ring wiring SL1 adjacent to each of the region 1A and the region 2A.

The second modification differs from the first modification in the following points. In the portion of the absorption region PA provided between the region 1A and the region 3A, the absorption region PA extends to a position overlapping, in plan view, with the seal ring wiring SL1 and partially surrounds the outer periphery of the region 1A in plan view, but does not surround the outer periphery of the region 3A. In the portion of the absorption region PA provided between the region 2A and the region 3A, the absorption region PA extends to a position overlapping, in plan view, with the seal ring wiring SL1 and partially surrounds the outer periphery of the region 2A in plan view, but does not surround the outer periphery of the region 3A.

In the second modification, compared with the first modification, a detouring distance of the current path of the leakage current I_{C} is shorter, so the ability to absorb the leakage current I_{C} is superior in the first modification than in the second modification. However, in the second modification, compared with the first modification, overall power consumption in the semiconductor device 100 can be further reduced.

### Third Modification

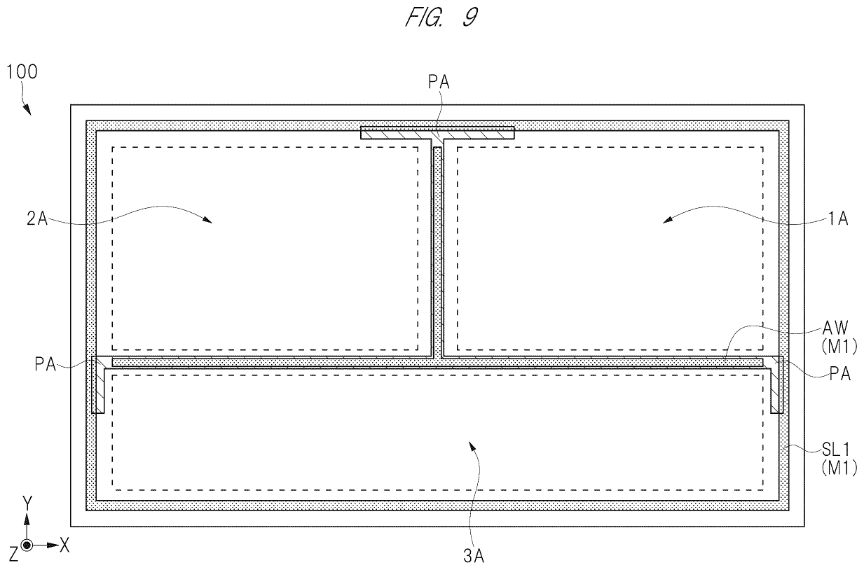

Hereinafter, a semiconductor device 100 according to a third modification of the first embodiment will be described with reference to FIG. 9. In the following description, differences from the first modification will mainly be described, and overlapping points with the first modification will be omitted.

As illustrated in FIG. 9, in the third modification, the absorption region PA partially surrounds an outer periphery of each of the region 1A, the region 2A, and the region 3A in plan view. That is, the absorption region PA overlaps, in plan view, with a portion of the seal ring wiring SL1 adjacent to each of the region 1A, the region 2A, and the region 3A.

The third modification differs from the first modification in the following points. In the portion of the absorption region PA provided between the region 1A and the region 3A, the absorption region PA extends to a position overlapping, in plan view, with the seal ring wiring SL1 and partially surrounds the outer periphery of the region 3A in plan view, but does not surround the outer periphery of the region 1A. In the portion of the absorption region PA provided between the region 2A and the region 3A, the absorption region PA extends to a position overlapping, in plan view, with the seal ring wiring SL1 and partially surrounds the outer periphery of the region 3A in plan view, but does not surround the outer periphery of the region 2A.

In the third modification, compared with the first modification, a detouring distance of the current path of the leakage current I_{C} is shorter, so the ability to absorb the leakage current I_{C} is superior in the first modification than in the third modification. However, in the third modification, compared with the first modification, overall power consumption in the semiconductor device 100 can be further reduced.

### Fourth Modification

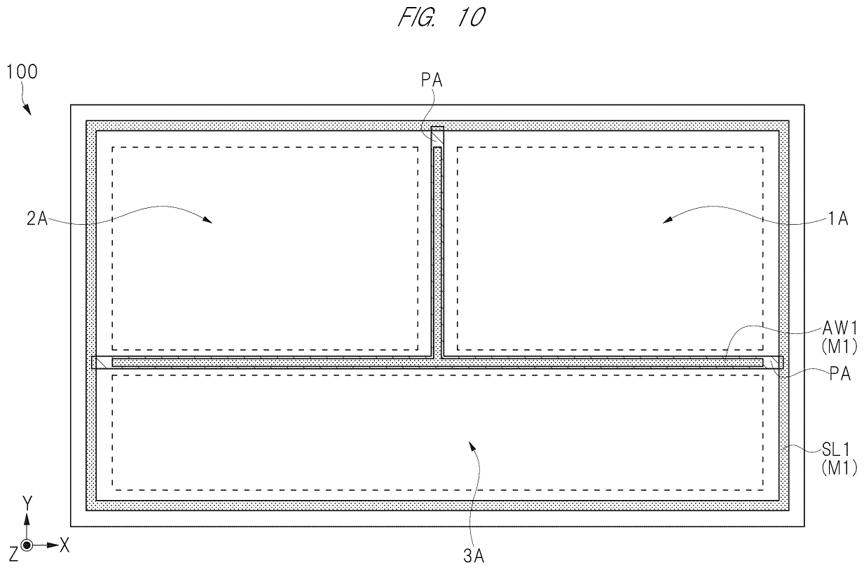

Hereinafter, a semiconductor device 100 according to a fourth modification of the first embodiment will be described with reference to FIG. 10. In the following description, differences from the first modification will mainly be described, and overlapping points with the first modification will be omitted.

As illustrated in FIG. 10, in the fourth modification, the absorption region PA extends to a position overlapping, in plan view, with the seal ring wiring SL1. However, in the fourth modification, the absorption region PA does not extend so as to partially surround an outer periphery of each of the region 1A, the region 2A, and the region 3A in plan view.

In the fourth modification, compared with the first, second, and third modifications, a detouring distance of the current path of the leakage current I_{C} is shorter, so the ability to absorb the leakage current I_{C} is superior in the first, second, and third modifications than in the fourth modification. However, in the fourth modification, compared with the first, second, and third modifications, overall power consumption in the semiconductor device 100 can be further reduced.

### Fifth Modification

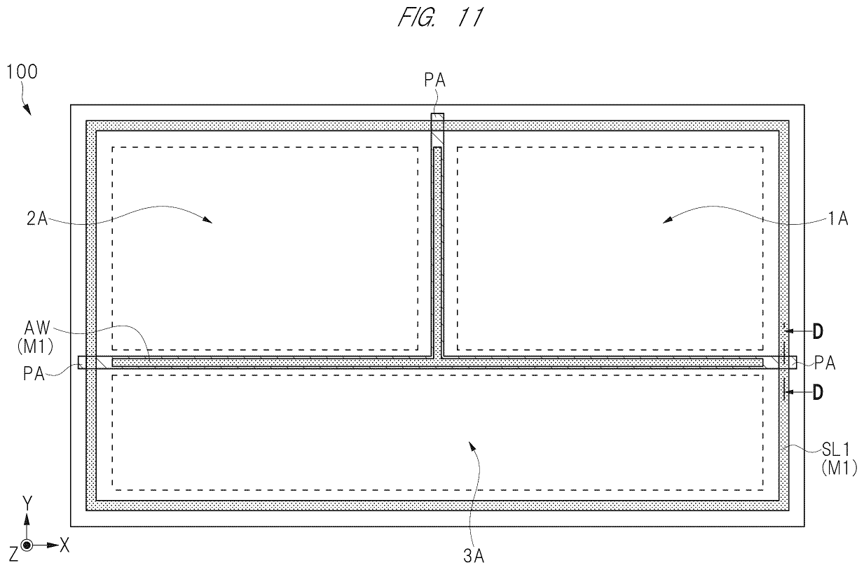

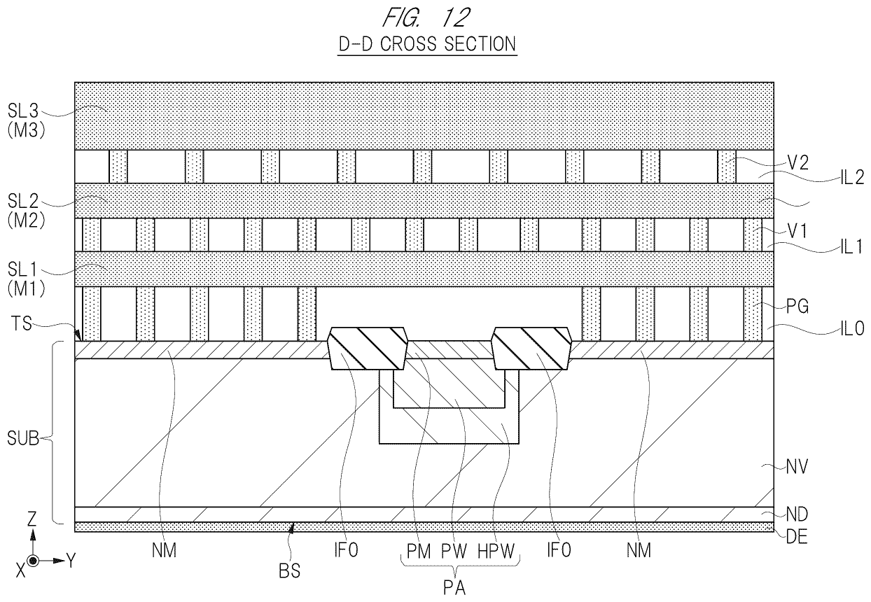

Hereinafter, a semiconductor device 100 according to a fifth modification of the first embodiment will be described with reference to FIGS. 11 and 12. In the following description, differences from the fourth modification will mainly be described, and overlapping points with the fourth modification will be omitted.

As illustrated in FIG. 11, in the fifth modification, similarly to the fourth modification, the absorption region PA does not extend so as to partially surround an outer periphery of each of the region 1A, the region 2A, and the region 3A in plan view. In the fifth modification, the absorption region PA extends so as to cross the seal ring wiring SL1 in plan view.

In the fifth modification, compared with the fourth modification, a detouring distance of the current path of the leakage current I_{C} is longer, so the ability to absorb the leakage current I_{C} is superior in the fifth modification than in the fourth modification. However, in the fifth modification, compared with the fourth modification, overall power consumption in the semiconductor device 100 increases.

As illustrated in FIG. 12, the plugs PG for connecting the semiconductor substrate SUB and the seal ring wiring SL1 is not formed on the absorption region PA so that the absorption region PA is not electrically connected to the seal ring wiring SL1.

### Second Embodiment

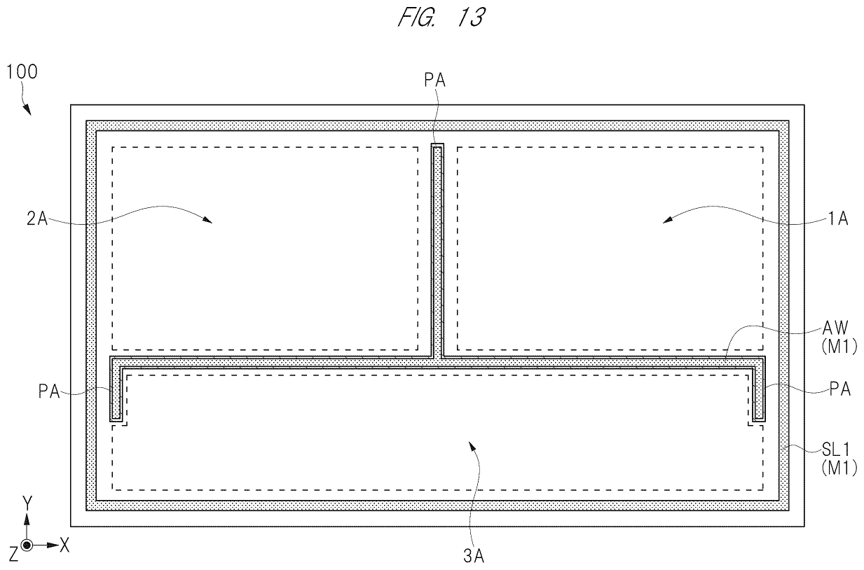

Hereinafter, a semiconductor device 100 according to a second embodiment will be described with reference to FIG. 13. In the following description, differences from the first embodiment will mainly be described, and overlapping points with the first embodiment will be omitted.

As illustrated in FIG. 13, similarly to the first embodiment, in the second embodiment, the absorption region PA is provided between the region 1A and the region 2A, between the region 1A and the region 3A, and between the region 2A and the region 3A. However, in the second embodiment, the absorption region PA does not overlap, in plan view, with the seal ring wiring SL1 and is provided between the seal ring wiring SL1 and portions of the region 3A. The absorption wiring AW covers the absorption region PA in plan view.

In the second embodiment, the current path of the leakage current I_{C} is partially blocked. By detouring the current path of the leakage current I_{C}, the ability to absorb the leakage current I_{C} can be maintained to some extent. The junction leakage can be reduced by the amount corresponding to the reduction in the area of the absorption region PA. Accordingly, in the second embodiment, compared with the first embodiment, overall power consumption in the semiconductor device 100 can be reduced.

The technique of the second embodiment can be suitably used in a case where it is difficult to extend the absorption region PA to a position overlapping, in plan view, with the seal ring wirings SL1, SL2, and SL3, or in a case where the number of the plurality of MOSFETs 3Q and the plurality of MOSFETs 4Q in the region 3A is small and there is a margin to arrange the absorption region PA.

As described above, the present invention has been specifically described based on the embodiments, but the present invention is not limited to the above embodiments and can be variously modified without departing from the spirit thereof.

For example, the number of wiring layers is not limited to three layers such as the wirings M1, M2, and M3, but may be two layers or four layers or more.

In addition, although it has been described that the semiconductor device 100 (that is, the semiconductor substrate SUB) includes three regions, the number of regions included in the semiconductor device 100 may be two. In this case, for example, in a first region, an n-type power MOSFET is formed, and in a second region, a p-type MOSFET and an n-type MOSFET are formed as a control circuit for controlling operation of the power MOSFET formed in the first region.

Further, although a trench gate type power MOSFET has been described as a vertical field-effect transistor (that is, a power semiconductor) formed in the region 1A (that is, the first region of the semiconductor substrate SUB) and the region 2A (that is, the second region of the semiconductor substrate SUB) of the semiconductor device 100 (that is, the semiconductor substrate SUB), the device is not limited to the power MOSFET and may be an Insulated Gate Bipolar Transistor (IGBT).

Furthermore, the power MOSFET is not limited to n-type but may be p-type. In that case, a conductivity type of the semiconductor substrate SUB and each impurity region is configured as a conductivity type opposite to the conductivity type described in the above embodiments.

What is claimed is:

1. A semiconductor device comprising:
a semiconductor substrate of a first conductivity type, the semiconductor substrate having an upper surface and a lower surface;
a first field-effect transistor of vertical type, the first field-effect transistor being formed in a first region of the semiconductor substrate and being a power semiconductor;
a second field-effect transistor formed in a second region, which is adjacent to the first region, of the semiconductor substrate, and configured to control operation of the first field-effect transistor;
a seal ring wiring formed in an annular shape so as to surround the first region and the second region in plan view, and formed on the upper surface of the semiconductor substrate; and
an impurity region formed in the semiconductor substrate so as to reach a predetermined depth from the upper surface of the semiconductor substrate and having a second conductivity type opposite to the first conductivity type,
wherein the impurity region is provided between the first region and the second region so as to extend to a position overlapping, in plan view, with the seal ring wiring, and
wherein a ground potential is supplied to the impurity region.

2. The semiconductor device according to claim 1,
wherein a third field-effect transistor of vertical type is formed in a third region, which is adjacent to each of the first region and the second region, of the semiconductor substrate, the third field-effect transistor being a power semiconductor,
wherein the seal ring wiring formed on the upper surface of the semiconductor substrate is formed in the annular shape so as to surround the first region, the second region, and the third region in plan view, and
wherein the impurity region is provided between the first region and the second region, between the first region and the third region, and between the second region and the third region so as to extend to the position overlapping, in plan view, with the seal ring wiring.

3. The semiconductor device according to claim 2,
wherein each of the first field-effect transistor and the second field-effect transistor is a power MOSFET.

4. The semiconductor device according to claim 3, further comprising
a first wiring formed on the upper surface of the semiconductor substrate and electrically connected to the impurity region,
wherein the first wiring is provided between the first region and the second region, between the first region and the third region, and between the second region and the third region so as to cover a portion of the impurity region in plan view, and is separated from the seal ring wiring.

5. The semiconductor device according to claim 4, further comprising
a drain electrode formed on the lower surface of the semiconductor substrate,
wherein the seal ring wiring is electrically connected to the drain electrode via the semiconductor substrate, and
wherein the impurity region and the first wiring are electrically insulated from the seal ring wiring.

6. The semiconductor device according to claim 3,
wherein the first field-effect transistor includes,
in the first region, a first trench formed in the semiconductor substrate so as to reach a predetermined depth from the upper surface of the semiconductor substrate,
a first gate electrode formed in the first trench via a first gate insulating film,
in the first region, a first body region of the second conductivity type formed in the semiconductor substrate so that a depth from the upper surface of the semiconductor substrate is shallower than a depth of the first trench, and
a first source region of the first conductivity type formed in the first body region,
wherein the third field-effect transistor includes,
in the third region, a second trench formed in the semiconductor substrate so as to reach a predetermined depth from the upper surface of the semiconductor substrate,
a second gate electrode formed in the second trench via a second gate insulating film,
in the third region, a second body region of the second conductivity type formed in the semiconductor substrate so that a depth from the upper surface of the semiconductor substrate is shallower than a depth of the second trench, and
a second source region of the first conductivity type formed in the second body region, and
wherein the second field-effect transistor includes,
in the second region, a first well region of the second conductivity type formed in the semiconductor substrate so as to reach a predetermined depth from the upper surface of the semiconductor substrate,
a diffusion region of the first conductivity type formed in the first well region and constituting a source region or a drain region of the second field-effect transistor, and
a third gate electrode formed on the first well region via a third gate insulating film.

7. The semiconductor device according to claim 6,
wherein a depth of the impurity region is greater than a depth of the first body region and a depth of the second body region.

8. The semiconductor device according to claim 3,
wherein the impurity region extends so as to cross the seal ring wiring in plan view.

9. The semiconductor device according to claim 3,
wherein the impurity region overlaps, in plan view, with a portion of the seal ring wiring that surrounds the first region and the third region.

10. The semiconductor device according to claim 3,
wherein the impurity region overlaps, in plan view, with portions of the seal ring wiring that are adjacent to respective portions of the first region and the third region.

11. The semiconductor device according to claim 10,
wherein the impurity region overlaps, in plan view, with a portion of the seal ring wiring that is adjacent to a portion of the second region.

12. A semiconductor device comprising:
a semiconductor substrate of a first conductivity type, the semiconductor substrate having an upper surface and a lower surface;
a first field-effect transistor of vertical type, the first field-effect transistor being formed in a first region of the semiconductor substrate and being a power semiconductor;
a second field-effect transistor formed in a second region, which is adjacent to the first region, of the semiconductor substrate, and configured to control operation of the first field-effect transistor;
a seal ring wiring formed in an annular shape so as to surround the first region and the second region in plan view, and formed on the upper surface of the semiconductor substrate; and
an impurity region formed in the semiconductor substrate so as to reach a predetermined depth from the upper surface of the semiconductor substrate and having a second conductivity type opposite to the first conductivity type,
wherein the impurity region is provided between the first region and the second region, and between the seal ring wiring and a portion of the second region, and
wherein a ground potential is supplied to the impurity region.

13. The semiconductor device according to claim 12,
wherein a third field-effect transistor of vertical type is formed in a third region, which is adjacent to each of the first region and the second region, of the semiconductor substrate, the third field-effect transistor being a power semiconductor,
wherein the seal ring wiring formed on the upper surface of the semiconductor substrate is formed in the annular shape so as to surround the first region, the second region, and the third region in plan view, and
wherein the impurity region is provided between the first region and the second region, between the first region and the third region, between the second region and the third region, and between the seal ring wiring and the portion of the second region.

14. The semiconductor device according to claim 13,
wherein each of the first field-effect transistor and the second field-effect transistor is a power MOSFET.

15. The semiconductor device according to claim 14, further comprising:
a first wiring formed on the upper surface of the semiconductor substrate so as to cover the impurity region in plan view, and electrically connected to the impurity region; and
a drain electrode formed on the lower surface of the semiconductor substrate,
wherein the seal ring wiring is electrically connected to the drain electrode via the semiconductor substrate, and
wherein the impurity region and the first wiring are electrically insulated from the seal ring wiring.

16. The semiconductor device according to claim 14,
wherein the first field-effect transistor includes,
in the first region, a first trench formed in the semiconductor substrate so as to reach a predetermined depth from the upper surface of the semiconductor substrate,
a first gate electrode formed in the first trench via a first gate insulating film,
in the first region, a first body region of the second conductivity type formed in the semiconductor substrate so that a depth from the upper surface of the semiconductor substrate is shallower than a depth of the first trench, and
a first source region of the first conductivity type formed in the first body region,
wherein the third field-effect transistor includes,
in the third region, a second trench formed in the semiconductor substrate so as to reach a predetermined depth from the upper surface of the semiconductor substrate,
a second gate electrode formed in the second trench via a second gate insulating film,
in the third region, a second body region of the second conductivity type formed in the semiconductor substrate so that a depth from the upper surface of the semiconductor substrate is shallower than a depth of the second trench, and
a second source region of the first conductivity type formed in the second body region, and
wherein the second field-effect transistor includes,
in the second region, a first well region of the second conductivity type formed in the semiconductor substrate so as to reach a predetermined depth from the upper surface of the semiconductor substrate,
a diffusion region of the first conductivity type formed in the first well region and constituting a source region or a drain region of the second field-effect transistor, and
a third gate electrode formed on the first well region via a third gate insulating film.

17. The semiconductor device according to claim 16,
wherein a depth of the impurity region is greater than a depth of the first body region and a depth of the second body region.

18. The semiconductor device according to claim 14,
wherein the impurity region does not overlap with the seal ring wiring in plan view.
